(19) United States
(12) Patent Application Publication
(10) Pub. No.: US 2026/0142604 A1
(43) Pub. Date: May 21, 2026

(54) OPERATIONS FOR FAULT DETECTION IN ADJUSTABLE FREQUENCY DRIVES USING NEUTRAL VOLTAGE MONITORING AND AUTOMATIC FREQUENCY DRIVES USING THE SAME

(71) Applicant: Eaton Intelligent Power Limited, Dublin 4 (IE)

(72) Inventors: Irving A. Gibbs, Mills River, NC (US); Gabriel Teixeira Braga, Belo Horizonte (BR); Ronan Cristiano de Souza, Belo Horizonte (BR); Stan R. Simms, Arden, NC (US)

(21) Appl. No.: 18/953,239

(22) Filed: Nov. 20, 2024

(51) Int. Cl. H02P 29/028; G01R 31/52; H02P 27/06

(52) U.S. Cl. CPC H02P 29/028; G01R 31/52; H02P 27/06

(57) ABSTRACT

Adjustable frequency drives (AFDs) and methods of operating the same are described. An AFD includes a plurality of inverters having first terminals that are coupled to respective phases of a motor and having AC output terminals connected to one another at an AC neutral node. A voltage at the AC neutral node is detected. A root-mean-squared (RMS) voltage measurement is generated from the detected voltage. A potential ground fault is identified responsive to the generated RMS measurement. The AFD is controlled responsive to identification of the ground fault. Identifying a potential ground fault responsive to the generated RMS voltage measurement may include comparing the RMS voltage measurement to a reference value.

### BACKGROUND

The inventive subject matter relates to adjustable frequency drives (AFDs) and methods of operating the same and, more particularly, to fault detection apparatus and methods for adjustable frequency drives.

Adjustable frequency drives (AFDs) (also referred to as variable frequency drives and variable speed drives) are commonly used to control AC motor speed in motor drive applications. AFDs typically use inverters that are coupled to DC buses powered by an AC/DC converter (e.g., a rectifier). AFDs commonly use multilevel neutral-point clamped (NPC) inverters, particularly for applications in which relatively large output voltages are required. U.S. Pat. No. 5,910,892 to Lyons et al. and U.S. Pat. No. 6,058,031 to Lyons et al. describe motor drives that include multilevel NPC inverters.

Fault detection and protection is generally important in AFD applications. In particular, AFDs that use multi-level inverter topologies may be particularly vulnerable to damage arising from faults. Circuit protection elements, such as feeder protection relays, may be inadequate for protecting against such damage as they may be unable to detect certain fault conditions, such as ground faults within the AFD or the load connected to the AFD. Various schemes for ground fault detection in AFD application have been proposed, such as those described in “Fault Detection and Protection of Three-Level Neutral-Point-Clamped PWM Voltage Source Converters” by Wang et al. (Conference Record 2008 IEEE Industry Applications Society Annual Meeting) and “Identifying Ground Fault Location in High Resistance Grounded Systems Using Adjustable Speed Drive” by Wei et al. (2011 IEEE Energy Conversion Congress and Exposition).

### SUMMARY

Some embodiments provide methods of operating an adjustable frequency drive (AFD) comprising a plurality of inverters having first terminals that are coupled to respective phases of a motor and having AC output terminals connected to one another at an AC neutral node. The methods include detecting a voltage at the AC neutral node, generating a root-mean-squared (RMS) voltage measurement from the detected voltage, identifying a potential ground fault responsive to the generated RMS measurement, and controlling operation of the AFD responsive to identification of the ground fault. Identifying a potential ground fault responsive to the generated RMS voltage measurement may include comparing the RMS voltage measurement to a reference value.

In some embodiments, identifying a potential ground fault responsive to the generated RMS voltage measurement may include identifying a fault of the AC neutral responsive to the generated RMS voltage measurement.

In some embodiments, identifying a potential ground fault responsive to the generated RMS voltage measurement may include identifying a potential phase-to-ground fault responsive to the generated RMS voltage measurement. Identifying a potential phase-to-ground fault responsive to the generated RMS voltage measurement may include comparing the RMS voltage measurement to a reference value that corresponds to a drive frequency of the AFD and identifying the potential phase-to-ground fault responsive to the comparison. Comparing the RMS voltage measurement to a reference value that corresponds to a drive frequency of the AFD may be preceded by generating a plurality of reference values that correspond to respective different drive frequencies using measurements obtained by operation of the AFD.

The methods may further include identifying a phase of the potential phase-to-ground fault. The inverters may have respective DC links coupled thereto, wherein the DC links comprise respective DC neutral nodes. Generating identifying a phase of the potential phase-to-ground fault may include detecting respective DC neutral node voltages at respective ones of the DC neutral nodes, generating respective RMS voltage measurements for the respective DC neutral nodes from respective ones of the DC neutral node voltages, and identifying the phase of the potential phase-to-ground fault from the RMS voltage measurements for the respective DC neutral nodes.

Identifying the phase of the potential phase-to-ground fault from the RMS voltage measurements for the respective DC neutral nodes may include identifying a first phase having an RMS voltage measurement for a first DC neutral node for a first phase that is less than RMS voltage measurements for second and third DC neutral nodes for respective second and third phases, comparing the RMS voltage measurement for the first DC neutral node to scaled values of the RMS voltages for the second and third DC bus neutral nodes, and identifying an AC ground fault for the first phase based on the comparison of the RMS voltage measurement for the first DC neutral node to the scaled values of the RMS voltage measurements for the second and third DC neutral nodes.

In further embodiments, the methods may further include detecting a neutral-to-ground voltage for at least one of the DC neutral nodes, generating an RMS voltage measurement for the at least one of the DC neutral nodes from the detected neutral-to-ground voltage at the at least one of the DC neutral nodes, and identifying at least one ground fault for at least one of the DC neutral nodes from the generated RMS voltage measurement for the at least one of the neutral nodes.

In some embodiments, each of the DC links may include a positive bus and a negative bus and the methods may further include detecting a neutral-to-ground voltage for at least one of the DC neutral nodes, generating an average voltage measurement for the at least one of the DC neutral nodes from the detected neutral-to-ground voltage at the at least one of the DC neutral nodes, and identifying at least one ground fault for at least one of the positive or negative buses from the generated RMS voltage measurement for the at least one of the neutral nodes.

Further embodiments may provide an AFD including a plurality of inverters having first terminals that are coupled to respective phases of a motor and having AC output terminals connected to one another at an AC neutral node. A control circuit is configured to detect a voltage at the AC neutral node, to generate a root-mean-squared (RMS) voltage measurement from the detected voltage, to identify a potential ground fault responsive to the generated RMS measurement, and to control operation of the AFD responsive to identification of the ground fault.

The control circuit may be configured to identify a fault of the AC neutral responsive to the generated RMS voltage measurement. The control circuit may be configured to identify a potential phase-to-ground fault responsive to the generated RMS voltage measurement.

The control circuit may be configured to compare the RMS voltage measurement to a reference value that corresponds to a drive frequency of the AFD and to identify the potential phase-to-ground fault responsive to the comparison. The control circuit may be configured to generate a plurality of reference values that correspond to respective different drive frequencies using measurements obtained by operation of the AFD. The control circuit may be configured to identify a phase of the potential phase-to-ground fault. The AFD may further include respective DC links coupled to the inverter, the DC links comprising respective DC neutral nodes, and the control circuit may be configured to detect respective DC neutral node voltages at respective ones of the DC neutral nodes, to generate respective RMS voltage measurements for the respective DC neutral nodes from respective ones of the DC neutral node voltages, and to identify the phase of the potential phase-to-ground fault from the RMS voltage measurements for the respective DC neutral nodes. The control circuit may be configured to detect a neutral-to-ground voltage for at least one of the DC neutral nodes, to generate an RMS voltage measurement for the at least one of the DC neutral nodes from the detected neutral-to-ground voltage at the at least one of the DC neutral nodes, and to identify at least one ground fault for at least one of the DC neutral nodes from the generated RMS voltage measurement for the at least one of the neutral nodes. Each of the DC links may include a positive bus and a negative bus and the control circuit may be configured to detect a neutral-to-ground voltage for at least one of the DC neutral nodes, to generate an average voltage measurement for the at least one of the DC neutral nodes from the detected neutral-to-ground voltage at the at least one of the DC neutral nodes, and to identify at least one ground fault for at least one of the positive or negative buses from the generated RMS voltage measurement for the at least one of the neutral nodes.

### BRIEF DESCRIPTION OF THE DRAWINGS

FIG. 1 is a schematic illustrating an AFD in which embodiments of the invention may be implemented.

FIG. 2 is a schematic illustrating DC bus connections of the AFD of FIG. 1.

FIG. 3 is a schematic illustrating a 5-level inverter configuration for the AFD of FIGS. 1 and 2.

FIG. 4 is a schematic illustrating a control and fault monitoring apparatus for an AFD according to some embodiments.

FIGS. 5-8 are flowcharts illustrating operations of the apparatus of FIG. 4 according to further embodiments.

### DETAILED DESCRIPTION

The inventive concept will be described more fully hereinafter with reference to the accompanying figures, in which embodiments of the inventive concept are shown. This inventive concept may, however, be embodied in many alternate forms and should not be construed as limited to the embodiments set forth herein.

Accordingly, while the inventive concept is susceptible to various modifications and alternative forms, specific embodiments thereof are shown by way of example in the drawings and will herein be described in detail. It should be understood, however, that there is no intent to limit the inventive concept to the particular forms disclosed, but on the contrary, the inventive concept is to cover all modifications, equivalents, and alternatives falling within the spirit and scope of the inventive concept as defined by the claims. Like numbers refer to like elements throughout the description of the figures.

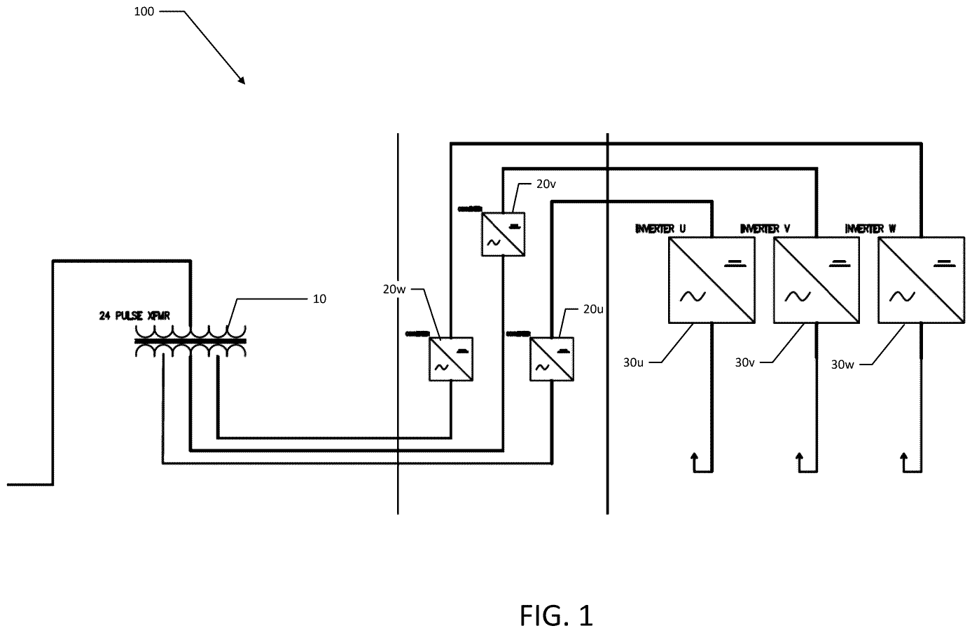

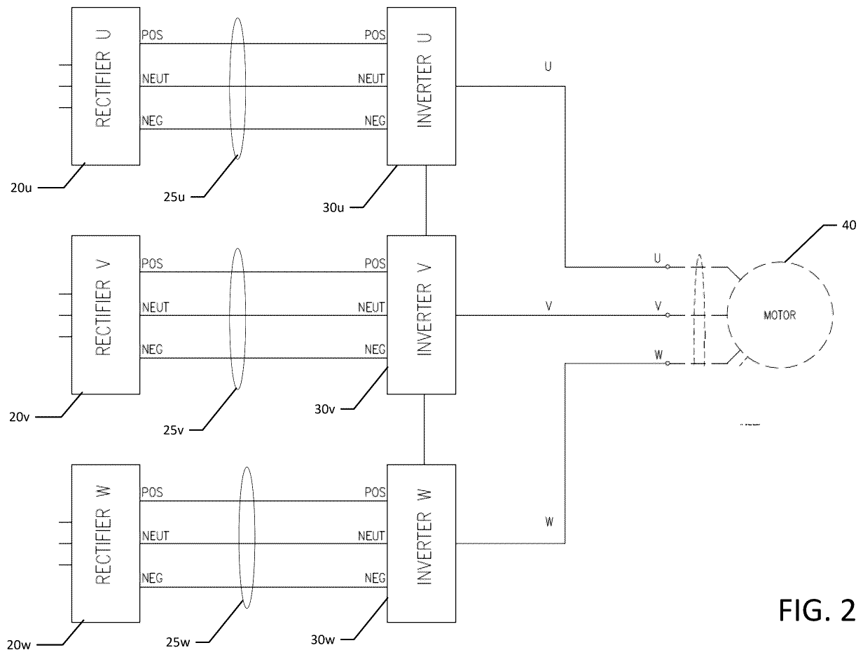

FIG. 1 illustrates an AFD 100 in which embodiments of the inventive concept may be implemented. The AFD 100 includes a drive isolation transformer 10 having a primary winding configured to receive AC power. Secondary windings of the transformer are connected to respective u, v and w phase rectifier circuits 20u, 20v, 20w, which feed respective u, v and w phase inverters 30u, 30v, 30w. The inverters 30u, 30v, 30w are configured to be connected to a motor 40, as shown in FIG. 2. As further illustrated in FIG. 2, the rectifiers 20u, 20v, 20w are connected to the respective inverters 30u, 30v, 30w by respective sets 25u, 25v, 25w of positive, negative and neutral buses. The respective inverters 30u, 30v, 30w drive respective phases u, v, w connected to the motor 40.

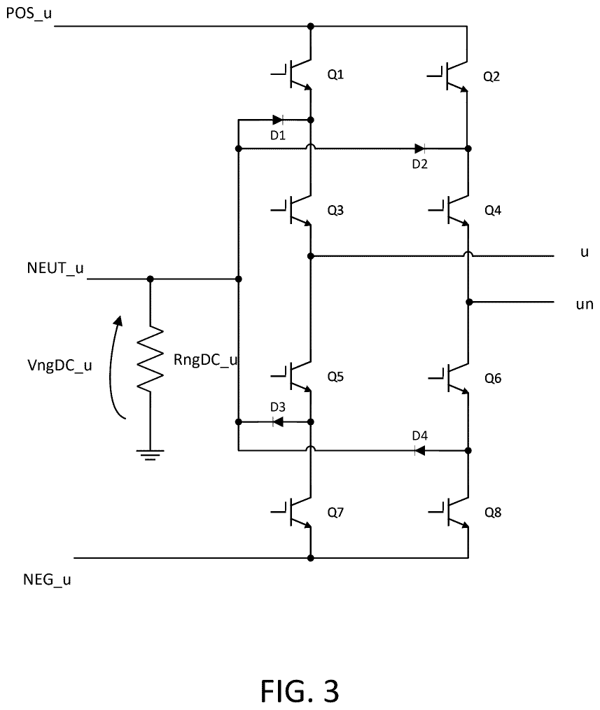

FIG. 3 illustrates an exemplary 5-level neutral point clamped (NPC) converter architecture for the inverters 30u, 30v, 30w. The 5-level inverter includes transistors Q1-Q8 and diodes D1-D4 connected in an H-bridge configuration. The transistors Q1-Q8 may be, for example, insulated gate bipolar transistors (IGBTs), but it will be appreciated that other types of transistors may be used. The positive DC bus POS_u is connected to the upper transistors Q1, Q2 and the negative bus NEG_u is connected to lower transistors Q7, Q8. The DC neutral bus NEUT_u is connected to junctions of a first pair D1, D2 of diodes and a second pair D3, D4 of diodes, and to a ground via a neutral grounding resistance RngDC_u. A neutral-to-ground voltage VngDC_u may be sensed directly or indirectly (e.g., using a voltage divider coupled between the neutral bus NEUT_u and ground). A phase conductor u is connected to the junctions of a first transistor pair Q3, Q5 and a neutral conductor un is connected to the junction of a second transistor pair Q4,Q6. The inverter illustrated in FIG. 3 is for the u phase but it will be appreciated that the V and w phase inverters may have an identical structure.

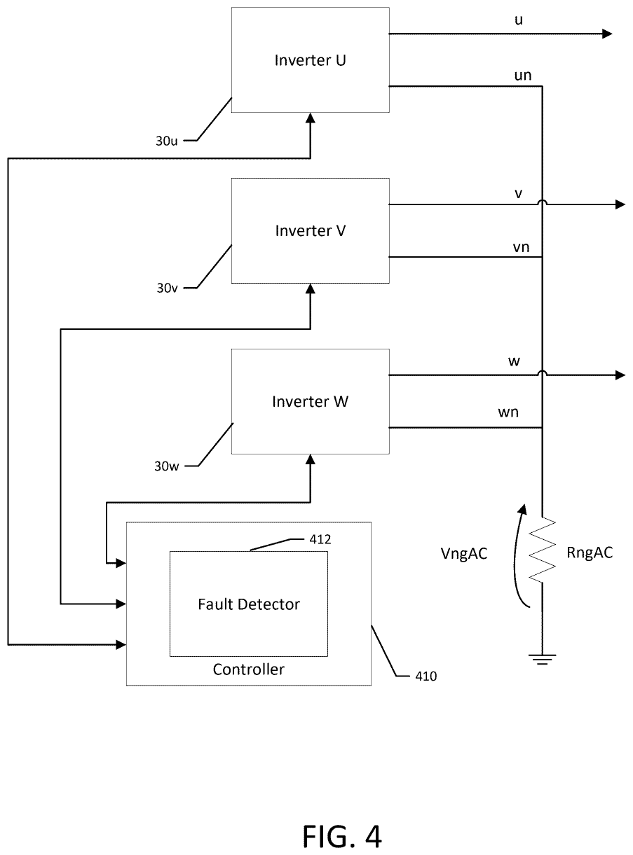

FIG. 4 illustrates an apparatus for control and fault detection for the AFD arrangements shown in FIGS. 1-3. A control circuit 410 is coupled to the inverters 30u, 30v, 30w. The control circuit 410 may include, for example, circuitry configured to control transistors or other semiconductor switches in the inverters 30u, 30v, 30w (e.g., the transistors Q1-Q8 shown in FIG. 3). It will be appreciated that the control circuit 410 may include any of a number of types of digital and/or analog circuits, such as a microcontroller or other processor combined with memory and interface circuitry for interfacing with the inverters 30u, 30v, 30w and other circuitry in the AFD. The control circuit 410 may be configured to receive various information regarding the operational state of the inverters 30u, 30v, 30w and to provide control signals to the inverters 30u, 30v, 30w and to other devices, such as other controllers, displays, alarm annunciators, and the like. States monitored may include voltages of the respective positive, negative and neutral buses of the DC links 25u, 25v, 25w, neutral-to-ground voltages for the neutral buses of the DC links 25u, 25v, 25w and a neutral-to-ground voltage VngAC of the AC output, wherein the neutral terminals un, vn, wn of the inverters 30u, 30v, 30W are connected in common to ground via a neutral grounding resistance RngAC. These monitored voltages can be used to identify various faults by a fault detector circuit 412 of the control circuit 410 as described in detail below.

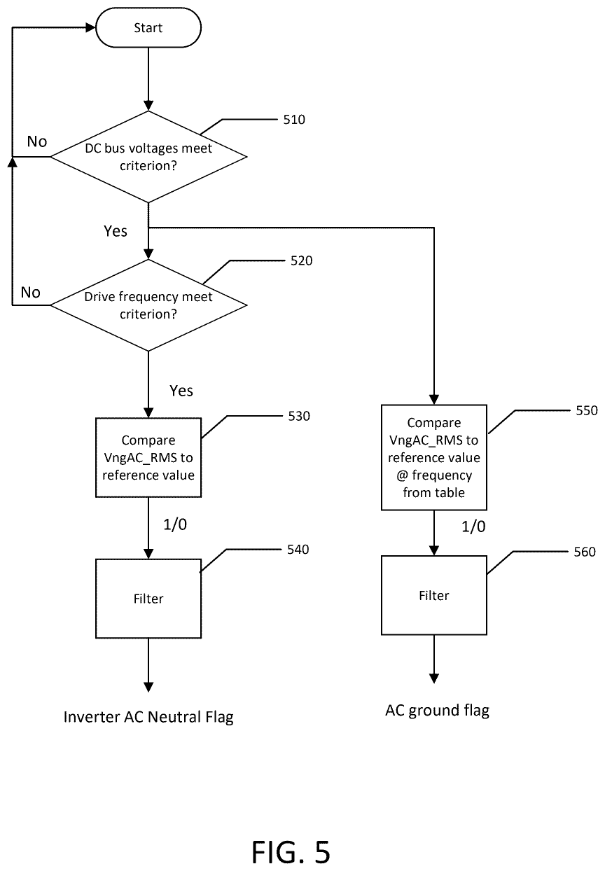

FIG. 5 illustrates operations that may be periodically conducted (e.g., each 1 millisecond) by the fault detector circuit 412 to set flags indicative of AC neutral-to-ground and phase-to-ground faults. Voltages of the positive and negative DC buses for all of the phases u, v, w and the drive output frequency may be checked to see if they meet certain criteria (blocks 510, 520) for accurate fault detection. For example, the DC bus voltages may be checked to see if they have magnitudes indicating that the DC links have been sufficiently charged. The drive frequency may be checked to see, for example, if it is sufficiently high to allow for accurate detection and discrimination of faults (e.g., greater than about 5-10 Hz). If these criteria are met, a root-mean-squared measurement VngAC_RMS of the AC neutral-to-ground voltage VngAC is compared to a reference value (blocks 510, 520, 530). This comparison may, for example, generate a logic value (e.g., “1” or “0”) indicating whether or not the RMS voltage measurement VngAC_RMS deviates with respect to the reference value (e.g., deviates below a predefined threshold value), which may be indicative of a possible ground fault. Such values generated over multiple monitoring cycles may be filtered (block 540) to generate an inverter AC neutral flag that, when set, indicates the presence of a ground fault on the AC neutral.

The RMS voltage measurement VngAC_RMS voltage measurement and other RMS measurements described herein may be obtained in any of a number of different ways. For example, such measurements may be generated using analog circuitry and/or by computation from digital voltage samples. Generation of the RMS voltage measurement VngAC_RMS and other RMS measurements may include sigma-delta or other signal processing techniques to reduce or avoid aliasing and/or other error-producing phenomena.

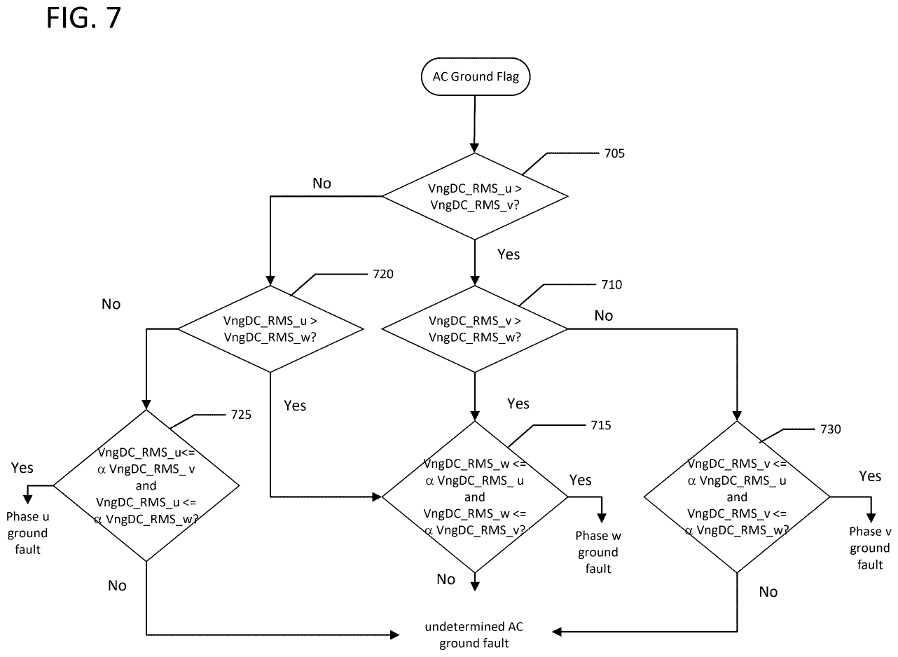

In parallel, the RMS measurement VngAC_RMS of the AC neutral-to-ground voltage VngAC may also be compared to a reference value associated with the current AC output frequency (block 550). Deviation with respect to the reference value (e.g., the RMS measurement VngAC_RMS exceeding a threshold value), may indicate the presence of an AC phase-to-ground fault. The reference values for the various output frequencies may be stored, for example, in a lookup table which, as explained below may be generated by operating the AFD in a calibration mode (i.e., under conditions in which no faults are present). The output of the comparison may be filtered (block 560) to generate an inverter AC ground flag. If this flag is set, it generally indicates the presence of a phase-to-ground fault. As further explained below with reference to FIG. 7, identification of the particular phase may be determined through additional measurements.

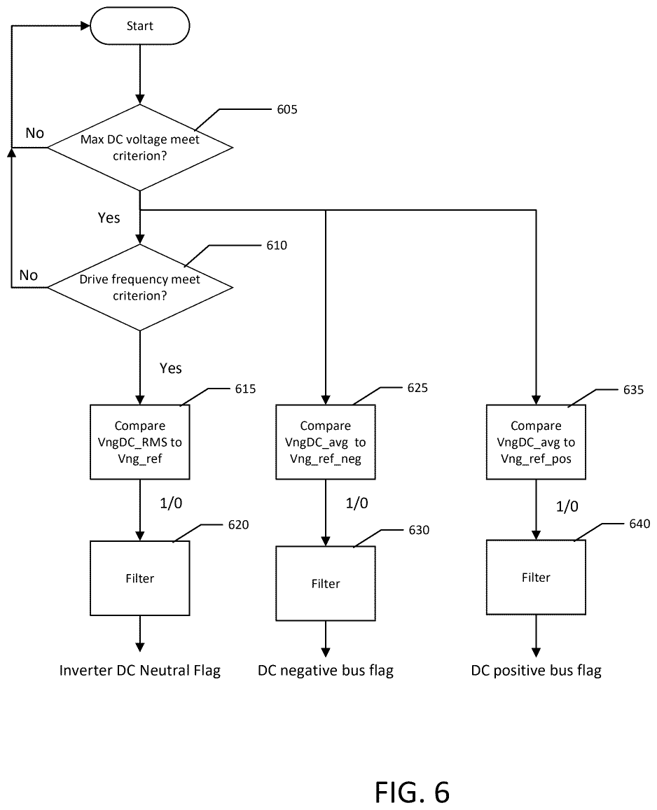

FIG. 6 illustrates operations that may be periodically (e.g., each 1 millisecond) conducted (e.g., each 1 millisecond) for each of the phases u, v and w to set flags indicative of DC neutral, positive DC bus and negative DC bus faults for the respective phases u, v, w. If the maximum magnitude of the positive and negative DC bus voltages for a given phase meets a predetermined criterion (e.g., deviates from a given reference value) and the drive frequency meets a predetermined criterion (e.g., is at a level that provides for accurate detection), an RMS measurement VngDC_RMS of the DC neutral-to-ground voltage for the given phase is compared to a reference value Vng_ref (blocks 605, 610, 615). The results of such comparisons may be filtered (block 620) over several cycles of measurements and testing to generate an inverter DC neutral flag which, if set, indicates a possible neutral-to-ground fault on the DC neutral of the given phase.

In parallel, an average value VngDC_avg of the DC neutral-to-ground voltage for the phase may be compared to a negative bus reference value Vng_ref_neg (block 625) and to a positive bus reference value Vng_ref_pos (block 635). These tests can determine whether the positive and/or negative DC buses have ground faults (e.g., a positive shift may indicate a negative DC bus ground fault and a negative shift may indicate a positive DC bus ground fault). The results of these comparisons are filtered (blocks 630, 640) to generate DC negative and positive bus flags which, if set, indicate potential positive or negative DC bus faults.

FIG. 7 illustrates operations that may be conducted to identify the phase of an AC phase to ground fault in response to generation of an AC ground flag as shown in FIG. 5. Various faults may be identified as follows:
a. if
   (1) the RMS measurement VngRMS_u for the neutral-to-ground voltage of the u phase is greater than the RMS measurement VngRMS_v for the neutral-to-ground voltage of the v phase,
   (2) the RMS measurement VngRMS_v for the neutral-to-ground voltage of the v phase is greater than the RMS measurement VngRMS_w for the neutral-to-ground voltage of the w phase,
   (3) the RMS measurement VngRMS_w for the neutral-to-ground voltage of the w phase is less than or equal to a predetermined fraction a (e. g, 0.9) of the RMS measurement VngRMS_u for the neutral-to-ground voltage of the u phase, and
   (4) the RMS measurement VngRMS_w for the neutral-to-ground voltage of the w phase is less than or equal to a predetermined fraction a of the RMS measurement VngRMS_v for the neutral-to-ground voltage of the v phase,
then a phase W ground fault may be identified (blocks 705,710, 715);
b. if
   (1) the RMS measurement VngRMS_u for the neutral-to-ground voltage of the u phase is less or equal to the RMS measurement VngRMS_v for the neutral-to-ground voltage of the v phase,
   (2) the RMS measurement VngRMS_u for the neutral-to-ground voltage of the u phase is greater than the RMS measurement VngRMS_w for the neutral-to-ground voltage of the w phase,
   (3) the RMS measurement VngRMS_w for the neutral-to-ground voltage of the w phase is less than or equal to predetermined fraction a of the RMS measurement VngRMS_u for the neutral-to-ground voltage of the u phase, and
   (4) the RMS measurement VngRMS_w for the neutral-to-ground voltage of the w phase is less than or equal to predetermined fraction a of the RMS measurement VngRMS_v for the neutral-to-ground voltage of the v phase,
then a phase W ground fault may be identified (blocks 705,720, 715);
c. if
   (1) the RMS measurement VngRMS_u for the neutral-to-ground voltage of the u phase is less or equal to the RMS measurement VngRMS_v for the neutral-to-ground voltage of the v phase,
   (2) the RMS measurement VngRMS_u for the neutral-to-ground voltage of the u phase is less than or equal to the RMS measurement VngRMS_w for the neutral-to-ground voltage of the w phase,
   (3) the RMS measurement VngRMS_u for the neutral-to-ground voltage of the u phase is less than or equal to a predetermined fraction a of the RMS measurement VngRMS_v for the neutral-to-ground voltage of the v phase, and
   (4) the RMS measurement VngRMS_u for the neutral-to-ground voltage of the u phase is less than or equal to a predetermined fraction a of the RMS measurement VngRMS_w for the neutral-to-ground voltage of the w phase,
then a phase U ground fault may be identified (blocks 705,720, 725); and
d. if
   (1) the RMS measurement VngRMS_u for the neutral-to-ground voltage of the u phase is greater than the RMS measurement VngRMS_v for the neutral-to-ground voltage of the v phase,
   (2) the RMS measurement VngRMS_v for the neutral-to-ground voltage of the v phase is less than or equal to the RMS measurement VngRMS_w for the neutral-to-ground voltage of the w phase,
   (3) the RMS measurement VngRMS_v for the neutral-to-ground voltage of the v phase is less than or equal to predetermined fraction a of the RMS measurement VngRMS_u for the neutral-to-ground voltage of the u phase, and
   (4) the RMS measurement VngRMS_v for the neutral-to-ground voltage of the v phase is less than or equal to predetermined fraction a of the RMS measurement VngRMS_w for the neutral-to-ground voltage of the w phase,
then a phase V ground fault may be identified (blocks 705,710, 730).
   Otherwise, the phase of the fault may remain undetermined.

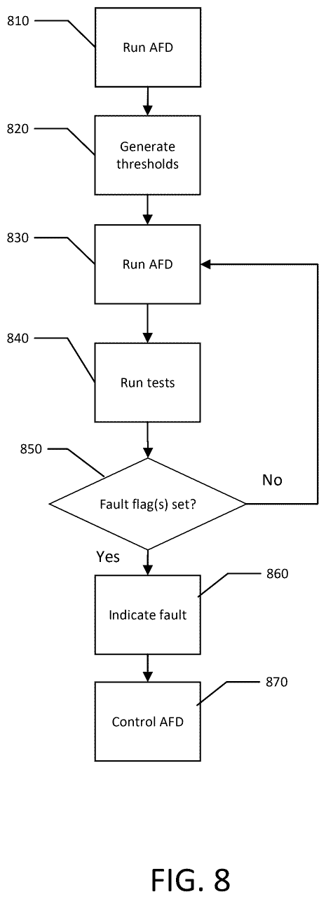

FIG. 8 illustrates operations according to further embodiments. In particular, the operations illustrated may be implemented by an AFD control system, such as the AFD control circuitry described above with reference to FIG. 4. An AFD with fault detection capabilities along the lines describe above may be run in a calibration phase to generate a table of reference values (e.g., thresholds) for detection of AC phase faults as discussed above with reference to FIG. 5 (blocks 810, 820). For example, root-mean-squared measurements (VngAC_RMS) of the AC neutral-to-ground voltage VngAC may be recorded at successive output frequency levels during a calibration operation in which the AFD frequency is ramped up. These measurements may be used to establish respective references for respective frequency levels for detecting potential AC phase-to-ground faults using the operations described with reference to FIG. 5.

Subsequently, the AFD may be operated to drive a motor (block 830). While operating, fault detection operations along the lines discussed above with reference to FIGS. 5-7 may be run (block 840). Upon detection of a fault indicator flag (block 850), a fault may be indicated using, for example, a visual and/or audio alert (block 860). Additional operations to control the AFD, such as terminating operations of the AFD to protect against damage to drive components and/or wiring, may be performed responsive to detection of the fault (block 870).

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof. Moreover, when an element is referred to as being “responsive” or “connected” to another element, it can be directly responsive or connected to the other element, or intervening elements may be present. In contrast, when an element is referred to as being “directly responsive” or “directly connected” to another element, there are no intervening elements present. As used herein the term “and/or” includes any and all combinations of one or more of the associated listed items and may be abbreviated as “/”.

Unless otherwise defined, all terms (including technical and scientific terms) used herein have the same meaning as commonly understood by one of ordinary skill in the art to which this inventive concept belongs. It will be further understood that terms used herein should be interpreted as having a meaning that is consistent with their meaning in the context of this specification and the relevant art and will not be interpreted in an idealized or overly formal sense unless expressly so defined herein.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the teachings of the disclosure. Although some of the diagrams include arrows on communication paths to show a primary direction of communication, it is to be understood that communication may occur in the opposite direction to the depicted arrows.

The embodiments described herein disclose apparatus and methods for detecting faults in an AFD. Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Further, some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Although the flowcharts show a specific order of execution, it is understood that the order of execution may differ from that which is depicted. Also, steps shown in succession in the flowcharts may be executed concurrently or with partial concurrence. Further, in some embodiments, one or more of the steps shown in the flowcharts may be skipped or omitted. In addition, any number of counters, state variables, flags, or messages might be added to the logical flows described herein, for purposes of enhanced utility, accounting, performance measurement, or providing troubleshooting aids, etc. It is understood that all such variations are within the scope of the present disclosure.

Where any component discussed herein is implemented in the form of software, any one of a number of programming languages may be employed such as, for example, C, C++, C#, Objective C, Java, Javascript, Perl, PHP, Visual Basic, Python, Ruby, Delphi, Flash, or other programming languages. Software components are stored in a memory and are executable by a processor, such as a microprocessor or microcontroller. In this respect, the term “executable” means a program file that is in a form that can ultimately be run by a processor. Examples of executable programs may be, for example, a compiled program that can be translated into machine code in a format that can be loaded into a random access portion of a memory and run by a processor, source code that may be expressed in proper format such as object code that is capable of being loaded into a random access portion of a memory and executed by a processor, or source code that may be interpreted by another executable program to generate instructions in a random access portion of a memory to be executed by a processor, etc. An executable program may be stored in any portion or component of a memory including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

A memory is defined herein as including both volatile and nonvolatile memory and data storage components. Volatile components are those that do not retain data values upon loss of power. Nonvolatile components are those that retain data upon a loss of power. Thus, a memory may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

The devices described herein may include multiple processors and multiple memories that operate in parallel processing circuits, respectively. In such a case, a local interface, such as a communication bus, may facilitate communication between any two of the multiple processors, between any processor and any of the memories, or between any two of the memories, etc. A local interface may comprise additional systems designed to coordinate this communication, including, for example, performing load balancing. A processor may be of electrical or of some other available construction.

Although the components described herein may be embodied in software or code executed by general purpose hardware, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, or other components, etc. Such technologies are generally well known by those skilled in the art and, consequently, are not described in detail herein.

Also, any logic, functionality or application described herein that comprises software or code can be embodied in any non-transitory computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system. The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method of operating an adjustable frequency drive comprising a plurality of inverters having first terminals that are coupled to respective phases of a motor and having AC output terminals connected to one another at an AC neutral node, the method comprising:
detecting a voltage at the AC neutral node;
generating a root-mean-squared (RMS) voltage measurement from the detected voltage;
identifying a potential ground fault responsive to the generated RMS measurement; and
controlling operation of the AFD responsive to identification of the ground fault.

2. The method of claim 1, wherein identifying a potential ground fault responsive to the generated RMS voltage measurement comprises comparing the RMS voltage measurement to a reference value.

3. The method of claim 1, wherein identifying a potential ground fault responsive to the generated RMS voltage measurement comprises identifying a fault of the AC neutral responsive to the generated RMS voltage measurement.

4. The method of claim 1, wherein identifying a potential ground fault responsive to the generated RMS voltage measurement comprises identifying a potential phase-to-ground fault responsive to the generated RMS voltage measurement.

5. The method of claim 4, wherein identifying a potential phase-to-ground fault responsive to the generated RMS voltage measurement comprises:
comparing the RMS voltage measurement to a reference value that corresponds to a drive frequency of the AFD; and
identifying the potential phase-to-ground fault responsive to the comparison.

6. The method of claim 5, wherein comparing the RMS voltage measurement to a reference value that corresponds to a drive frequency of the AFD is preceded by generating a plurality of reference values that correspond to respective different drive frequencies using measurements obtained by operation of the AFD.

7. The method of claim 5, further comprising identifying a phase of the potential phase-to-ground fault.

8. The method of claim 7, wherein the inverters have respective DC links coupled thereto, wherein the DC links comprise respective DC neutral nodes and wherein generating identifying a phase of the potential phase-to-ground fault comprises:
detecting respective DC neutral node voltages at respective ones of the DC neutral nodes;
generating respective RMS voltage measurements for the respective DC neutral nodes from respective ones of the DC neutral node voltages; and
identifying the phase of the potential phase-to-ground fault from the RMS voltage measurements for the respective DC neutral nodes.

9. The method of claim 8, wherein identifying the phase of the potential phase-to-ground fault from the RMS voltage measurements for the respective DC neutral nodes comprises:
identifying a first phase having an RMS voltage measurement for a first DC neutral node for a first phase that is less than RMS voltage measurements for second and third DC neutral nodes for respective second and third phases;
comparing the RMS voltage measurement for the first DC neutral node to scaled values of the RMS voltages for the second and third DC bus neutral nodes; and
identifying an AC ground fault for the first phase based on the comparison of the RMS voltage measurement for the first DC neutral node to the scaled values of the RMS voltage measurements for the second and third DC neutral nodes.

10. The method of claim 8, further comprising:
detecting a neutral-to-ground voltage for at least one of the DC neutral nodes;
generating an RMS voltage measurement for the at least one of the DC neutral nodes from the detected neutral-to-ground voltage at the at least one of the DC neutral nodes; and
identifying at least one ground fault for at least one of the DC neutral nodes from the generated RMS voltage measurement for the at least one of the neutral nodes.

11. The method of claim 8, wherein each of the DC links comprises a positive bus and a negative bus and wherein the method further comprises:
detecting a neutral-to-ground voltage for at least one of the DC neutral nodes;
generating an average voltage measurement for the at least one of the DC neutral nodes from the detected neutral-to-ground voltage at the at least one of the DC neutral nodes; and
identifying at least one ground fault for at least one of the positive or negative buses from the generated RMS voltage measurement for the at least one of the neutral nodes.

12. An AFD comprising:
a plurality of inverters having first terminals that are coupled to respective phases of a motor and having AC output terminals connected to one another at an AC neutral node; and
a control circuit configured to detect a voltage at the AC neutral node, to generate a root-mean-squared (RMS) voltage measurement from the detected voltage, to identify a potential ground fault responsive to the generated RMS measurement, and to control operation of the AFD responsive to identification of the ground fault.

13. The AFD of claim 12, wherein the control circuit is configured to identify a fault of the AC neutral responsive to the generated RMS voltage measurement.

14. The AFD of claim 13, wherein the control circuit is configured to identify a potential phase-to-ground fault responsive to the generated RMS voltage measurement.

15. The AFD of claim 14, wherein the control circuit is configured to compare the RMS voltage measurement to a reference value that corresponds to a drive frequency of the AFD and to identify the potential phase-to-ground fault responsive to the comparison.

16. The AFD of claim 15, wherein the control circuit is configured to generate a plurality of reference values that correspond to respective different drive frequencies using measurements obtained by operation of the AFD.

17. The AFD of claim 14, wherein the control circuit is configured to identify a phase of the potential phase-to-ground fault.

18. The AFD of claim 17, further comprising respective DC links coupled to the inverter, the DC links comprising respective DC neutral nodes, and wherein the control circuit is configured to detect respective DC neutral node voltages at respective ones of the DC neutral nodes, to generate respective RMS voltage measurements for the respective DC neutral nodes from respective ones of the DC neutral node voltages, and to identify the phase of the potential phase-to-ground fault from the RMS voltage measurements for the respective DC neutral nodes.

19. The AFD of claim 18, wherein the control circuit is configured to detect a neutral-to-ground voltage for at least one of the DC neutral nodes, to generate an RMS voltage measurement for the at least one of the DC neutral nodes from the detected neutral-to-ground voltage at the at least one of the DC neutral nodes, and to identify at least one ground fault for at least one of the DC neutral nodes from the generated RMS voltage measurement for the at least one of the neutral nodes.

20. The AFD of claim 18, wherein each of the DC links comprises a positive bus and a negative bus and wherein the control circuit is configured to detect a neutral-to-ground voltage for at least one of the DC neutral nodes, to generate an average voltage measurement for the at least one of the DC neutral nodes from the detected neutral-to-ground voltage at the at least one of the DC neutral nodes, and to identify at least one ground fault for at least one of the positive or negative buses from the generated RMS voltage measurement for the at least one of the neutral nodes.
